(19) United States
(12) Patent Application Publication
(10) Pub. No.: US 2026/0231401 A1
(43) Pub. Date: Aug. 6, 2026

(54) SEMICONDUCTOR DEVICE HAVING RESISTIVE VOLTAGE DIVIDER

(71) Applicant: Micron Technology, Inc., Boise, ID (US)

(72) Inventors: Kenichi Echigoya, Kanagawa (JP); Takamitsu Onda, Tokyo (JP)

(73) Assignee: Micron Technology, Inc., Boise, ID (US)

(21) Appl. No.: 19/458,445

(22) Filed: Jan. 23, 2026

Related U.S. Application Data
(60) Provisional application No. 63/752,988, filed on Feb. 3, 2025.

(51) Int. Cl. H10B 12/00; G11C 11/4074

(52) U.S. Cl. CPC H10B 12/50; G11C 11/4074

(57) ABSTRACT

An example apparatus includes a resistor pattern having a plurality of nodes, a plurality of transistors each having a first diffusion region coupled to an associated one of the plurality of nodes of the resistor pattern and a second diffusion region coupled in common to an output terminal. Each of the plurality of nodes of the resistor pattern is physically located over the first diffusion region of an associated one of the plurality of transistors.

### CROSS-REFERENCE TO RELATED APPLICATIONS

This application claims the filing benefit of U.S. Provisional Application No. 63/752,988, filed February 3, 2025. This application is incorporated by reference herein in its entirety and for all purposes.

### BACKGROUND

There is a case where a semiconductor device such as a DRAM includes a resistive voltage divider that generates an inner potential. The resistive voltage divider includes a plurality of resistive elements connected in series between input power supplies and a plurality of selection transistors respectively connected between each node located between the resistive elements and an output line. With this configuration, by turning any one of the selection transistors on, an inner potential obtained by resistive-dividing an input power supply appears on the output line. In a general resistive voltage divider, a node of a resistive element and a selection transistor are connected to each other via a coupling line located on an upper layer with respect to a resistive element. Accordingly, in addition to the resistance of the resistive element itself, the resistance of the coupling line, the resistance of a via conductor coupling the coupling line and the node of the resistive element to each other, and the resistance of a via conductor coupling the coupling line and the selection transistor to each other are added to the resistive voltage divider, so that there is a problem that the design of resistance values becomes complicated.

### BRIEF DESCRIPTION OF THE DRAWINGS

FIG. 1 is a schematic plan view showing a configuration of a resistive voltage divider according to a first embodiment of the present disclosure;

FIG. 2 is a schematic cross section along a line A-A shown in FIG. 1;

FIG. 3 is a circuit diagram of the resistive voltage divider;

FIG. 4 is a schematic plan view for explaining a planar shape of a resistor pattern in more detail;

FIG. 5 is a schematic plan view showing a configuration of a resistive voltage divider according to a second embodiment of the present disclosure;

FIG. 6 is a schematic plan view showing a configuration of a resistive voltage divider according to a third embodiment of the present disclosure;

FIG. 7 is a schematic plan view showing a configuration of a resistive voltage divider according to a fourth embodiment of the present disclosure;

FIG. 8 is a schematic plan view showing a configuration of a resistive voltage divider according to a fifth embodiment of the present disclosure; and

FIG. 9 is a schematic plan view showing a configuration of a resistive voltage divider according to a sixth embodiment of the present disclosure.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

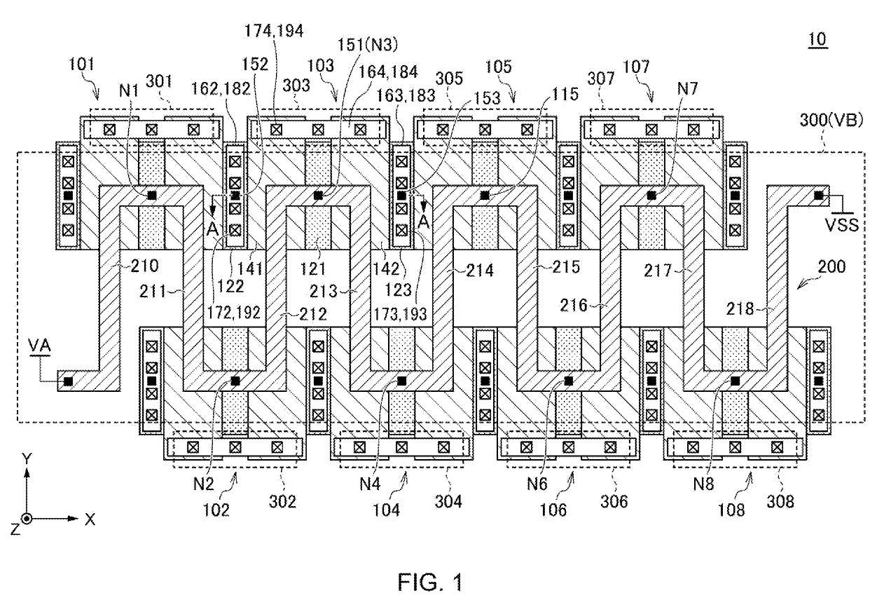

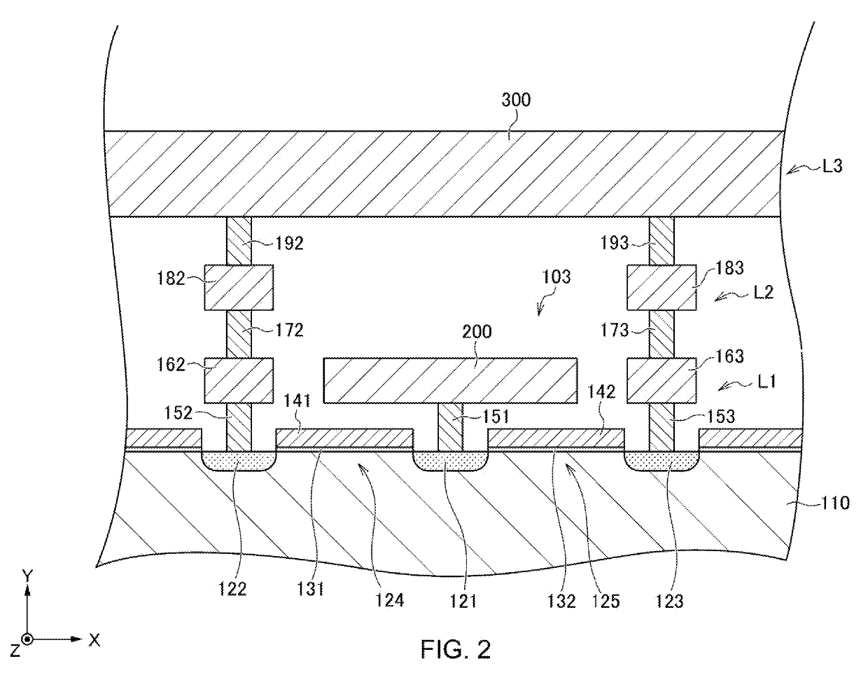

FIG. 1 is a schematic plan view showing a configuration of a resistive voltage divider 10 according to a first embodiment of the present disclosure. FIG. 2 is a schematic cross section along a line A-A shown in FIG. 1. The resistive voltage divider 10 shown in FIG. 1 includes a plurality of selection transistors 101 to 108, a resistor pattern 200 that meanders to overlap with the selection transistors 101 to 108, and an output line 300. An inner potential VA is supplied to one end of the resistor pattern 200 and a ground potential VSS is supplied to the other end of the resistor pattern 200. The resistor pattern 200 includes nodes N1 to N8 respectively allocated to the selection transistors 101 to 108. The selection transistors 101, 103, 105, and 107 constitute a group arranged in an X direction and the selection transistors 102, 104, 106, and 108 constitute another group arranged in the X direction. The group constituted of the selection transistors 101, 103, 105, and 107 and the group constituted of the selection transistors 102, 104, 106, and 108 are both arranged in a Y direction. In some examples, the X direction and the Y direction are perpendicular to each other.

Each of the selection transistors 101 to 108 is an N-channel MOS transistor. The selection transistors 101 to 108 have mutually the same configuration and a cross-sectional configuration of the selection transistor 103 is shown in FIG. 2 in a representative manner. Each of the selection transistors 101 to 108 includes a diffusion region 121 that functions as a drain, diffusion regions 122 and 123 each of which functions as a source, a gate electrode 141 that convers a channel region 124 located between the diffusion regions 121 and 122 via a gate insulating film 131, and a gate electrode 142 that convers a channel region 125 located between the diffusion regions 121 and 123 via a gate insulating film 132. Each of the nodes N1 to N8 of the resistor pattern 200 is located over the diffusion region 121 of the corresponding one of the selection transistors 101 to 108. Each of the nodes N1 to N8 is connected to the diffusion region 121 of the corresponding one of the selection transistors 101 to 108 via a via conductor 151. The diffusion region 122 of the selection transistor 103 may be shared with another diffusion region that functions as the source of the selection transistor 101. The diffusion region 123 of the selection transistor 103 may be shared with another diffusion region that functions as the source of the selection transistor 105.

The resistor pattern 200 is formed of a wiring located on a conductor layer L1. The conductor layer L1 includes a conductor pattern 162 that overlaps with the diffusion region 122 and a conductor pattern 163 that overlaps with the diffusion region 123. The conductor patterns 162 and 163 are respectively connected to the diffusion regions 122 and 123 via via conductors 152 and 153. Conductor layers L2 and L3 are provided above the conductor layer L1 as viewed from a semiconductor substrate 110. The conductor layer L2 includes conductor patterns 182 and 183 that respectively overlap with the conductor patterns 162 and 163. The conductor patterns 182 and 183 are respectively connected to the conductor patterns 162 and 163 via via conductors 172 and 173. The conductor layer L3 includes an output line 300. The output line 300 is allocated in common to the selection transistors 101 to 108. The output line 300 is connected to the conductor patterns 182 and 183 via via conductors 192 and 193. In FIG. 1, a conductor pattern located on the conductor layer L3 is shown in a broken line.

Each of selection signals SEL1 to SEL8 is supplied to the gate electrodes 141 and 142 of each of the selection transistors 101 to 108 via the corresponding one of selection signal lines 301 to 308. That is, each of the selection transistors 101 to 108 includes two gate electrodes, thereby effectively increasing the gate width of each selection transistor twice. The selection signal lines 301 to 308 are located on the conductor layer L3. The selection signal lines 301 to 308 are connected to a conductor pattern 184 located on the conductor layer L2 via a via conductor 194. The conductor pattern 184 is connected to a conductor pattern 164 located on the conductor layer L1 via a via conductor 174. The conductor pattern 164 is connected in common to the gate electrodes 141 and 142 via a via conductor (not shown).

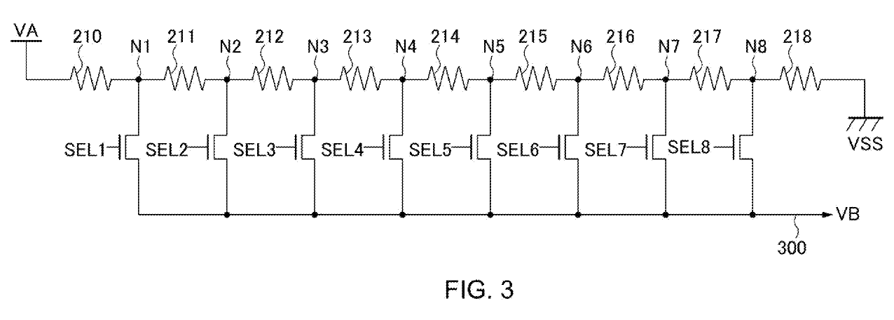

Accordingly, the resistive voltage divider 10 shown in FIG. 1 constitutes a circuit shown in FIG. 3. As shown in FIG. 3, one end (drain) of each of the selection transistors 101 to 108 is connected to the corresponding one of the nodes N1 to N8 of the resistor pattern 200, and other ends (sources) of the selection transistors 101 to 108 are connected in common to the output line 300. Each of the selection signals SEL1 to SEL 8 is supplied to the gate electrode of the corresponding one of the selection transistors 101 to 108. Any one of the selection signals SEL1 to SEL 8 is exclusively activated. As a result, by switching a selection signal to be activated among the selection signals SEL1 to SEL8, the level of an inner potential VB to be output to the output line 300 is changed.

The resistor pattern 200 includes a section 210 located between an end to which the inner potential VA is supplied and the node N1, a section 211 located between the nodes N1 and N2, a section 212 located between the nodes N2 and N3, a section 213 located between the nodes N3 and N4, a section 214 located between the nodes N4 and N5, a section 215 located between the nodes N5 and N6, a section 216 located between nodes N6 and N7, a section 217 located between nodes N7 and N8, and a section 218 located between the node N8 and an end to which the ground potential VSS is supplied. These sections 210 to 218 are connected in series between the end to which the inner potential VA is supplied and the end to which the ground potential VSS is supplied. Each of the sections 210 to 218 is located on the conductor layer L1 and does not route through any conductor pattern located on the conductor layers L2 and L3 that are upper layers.

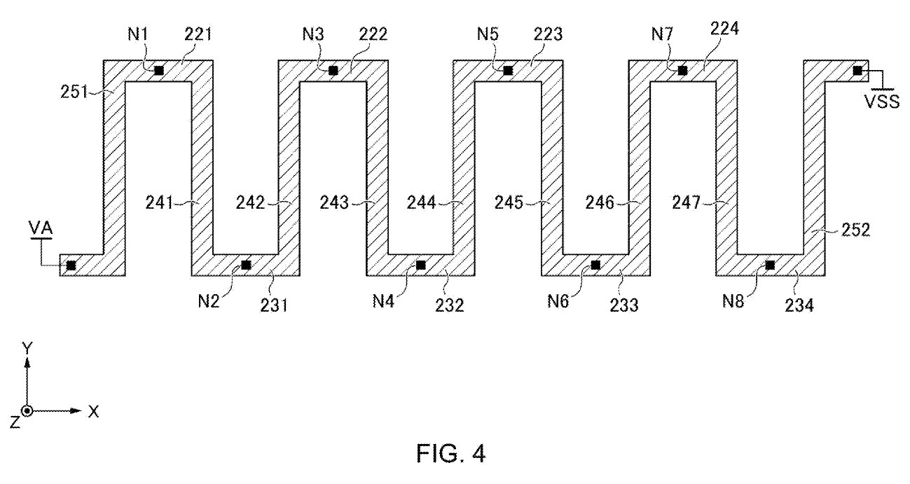

FIG. 4 is a schematic plan view for explaining a planar shape of the resistor pattern 200 in more detail. As shown in FIG. 4, the resistor pattern 200 includes a plurality of sections 221 to 224 and 231 to 234 extending in the X direction and a plurality of sections 241 to 247, 251, and 252 extending in the Y direction. The section 251 connects an end of the resistor pattern 200 to which the inner potential VA is supplied and one end of the section 221 to each other. The section 241 connects the other end of the section 221 and one end of the section 231 to each other. The section 242 connects the other end of the section 231 and one end of the section 222 to each other. The section 243 connects the other end of the section 222 and one end of the section 232 to each other. The section 244 connects the other end of the section 232 and one end of the section 223 to each other. The section 245 connects the other end of the section 223 and one end of the section 233 to each other. The section 246 connects the other end of the section 233 and one end of the section 224 to each other. The section 247 connects the other end of the section 224 and one end of the section 234 to each other. The section 252 connects the other end of the section 234 and an end of the resistor pattern 200 to which the ground potential VSS is supplied to each other. The nodes N1, N3, N5, and N7 are respectively located in the sections 221 to 224. The nodes N2, N4, N6, and N8 are respectively located in the sections 231 to 234.

As described above, the resistor pattern 200 of the resistive voltage divider 10 according to the present embodiment meanders and extends to overlap with the diffusion region 121 included in each of the selection transistors 101 to 108 and is connected to the diffusion region 121 of the corresponding one of the selection transistors 101 to 108 via the via conductor 151 provided on a position overlapping with the diffusion region 121. That is, since the resistor pattern 200 and each of the selection transistors 101 to 108 are directly connected to each other via the via conductor 151 without routing through the conductor layers L2 and L3, the resistance component added to the resistor pattern 200 is only the resistance component of the via conductor 151. Therefore, the design of resistance values of the resistive voltage divider 10 is facilitated and it becomes possible to adjust the level of the inner potential VB to be output to the output line 300 highly accurately.

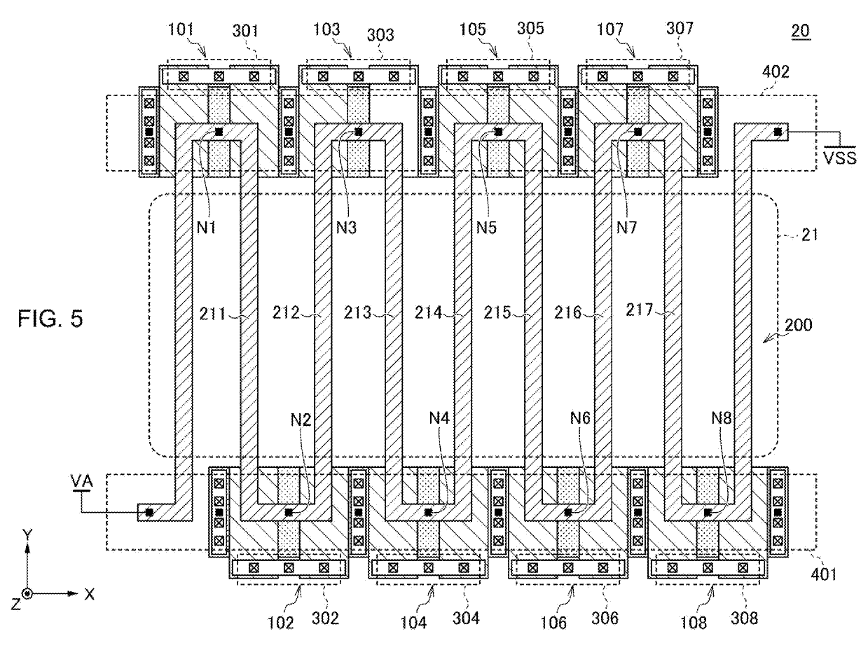

FIG. 5 is a schematic plan view showing a configuration of a resistive voltage divider 20 according to a second embodiment of the present disclosure. The resistive voltage divider 20 shown in FIG. 5 is different from the resistive voltage divider 10 according to the first embodiment in that the resistive voltage divider 20 has the distance in the Y direction between the group constituted of the selection transistors 101, 103, 105, and 107 and the group constituted of the selection transistors 102, 104, 106, and 108 increased and a region 21 in which a capacitor element is arranged is allocated between these groups. An output line 402 is allocated to the group constituted of the selection transistors 101, 103, 105, and 107 and an output line 401 is allocated to the group constituted of the selection transistors 102, 104, 106, and 108. The output line 401 and the output line 402 are short circuited. The capacitor element arranged in the region 21 may be an element having the same configuration as that of a cell capacitor of a DRAM. The region 21 overlaps with the sections 211 to 217 of the resistor pattern 200. Accordingly, the capacitor element arranged in the region 21 covers the sections 211 to 217 of the resistor pattern 200. In this manner, another circuit element such as a capacitor may be arranged between the selection transistors.

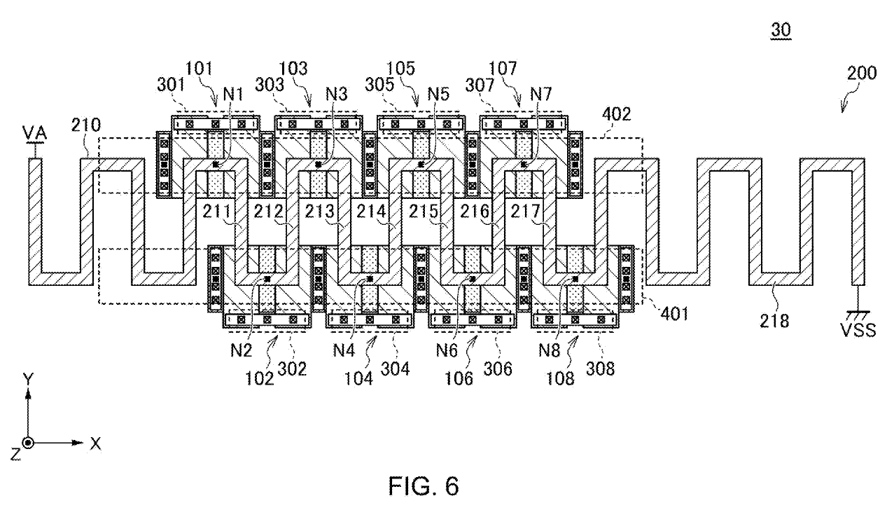

FIG. 6 is a schematic plan view showing a configuration of a resistive voltage divider 30 according to a third embodiment of the present disclosure. The resistive voltage divider 30 shown in FIG. 6 is different from the resistive voltage divider 10 according to the first embodiment in that the resistive voltage divider 30 has the length of the sections 210 and 218 located at the end of the resistor pattern 200 increased. The both sections 210 and 218 extend in a meander shape and have a length longer than those of other sections 211 to 217. Further, in the example shown in FIG. 6, the section 218 is longer than the section 210. According to the resistive voltage divider 30 shown in FIG. 6, the dynamic range of the inner potential VB that can be output is reduced, so that it is possible to reduce the control pitch of the inner potential VB using the selection signals SEL1 to SEL8.

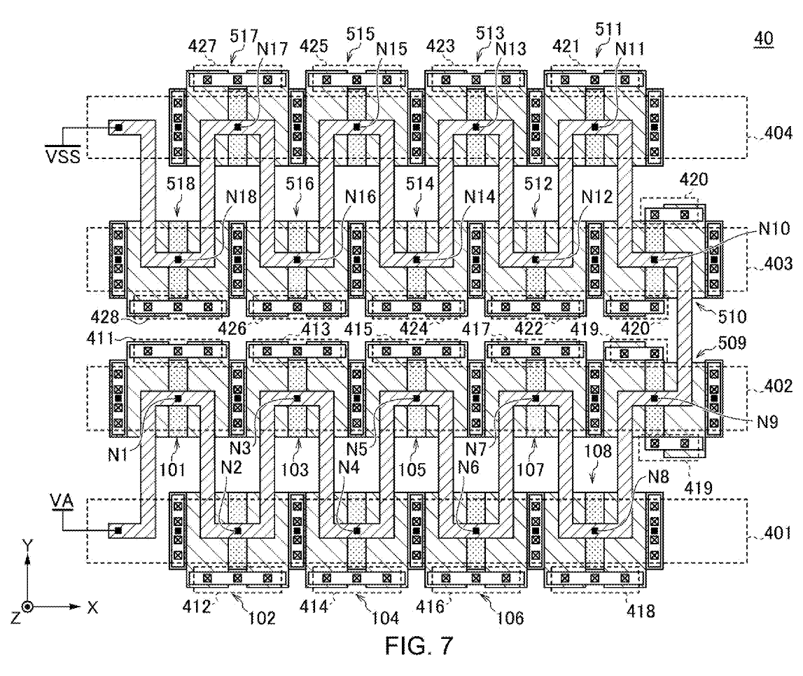

FIG. 7 is a schematic plan view showing a configuration of a resistive voltage divider 40 according to a fourth embodiment of the present disclosure. The resistive voltage divider 40 shown in FIG. 7 is different from the resistive voltage divider 10 according to the first embodiment in that transistors 509 to 518 are added to the resistive voltage divider 40 and the resistor pattern 200 includes nodes N9 to N18. Each selection signal is supplied to the gate electrode of each of the transistors 101 to 108 and 509 to 518 via the corresponding one of selection signal lines 411 to 428. The output line 401 is allocated to the group constituted of the selection transistors 102, 104, 106, and 108 extending in the X direction, the output line 402 is allocated to a group constituted of the selection transistors 101, 103, 105, 107, and 509 extending in the X direction, an output line 403 is allocated to a group constituted of the selection transistors 510, 512, 514, 516, and 518 extending in the X direction, and an output line 404 is allocated to a group constituted of the selection transistors 511, 513, 515, and 517 extending in the X direction. The output lines 401 to 404 are short circuited. Here, in a case where the end of the resistor pattern 200 to which the inner potential VA is supplied is a starting point and the end of the resistor pattern 200 to which the ground potential VSS is supplied is an end point, in the sections in which the nodes N1 to N9 are provided, the resistor pattern 200 extends in a meander shape towards a +X direction and in the sections in which the nodes N10 to N18 are provided, the resistor pattern 200 extends in a meander shape towards a -X direction. By turning the resistor pattern 200 in a meander shape in this manner, it is possible to reduce the size of the resistive voltage divider 40 in the X direction.

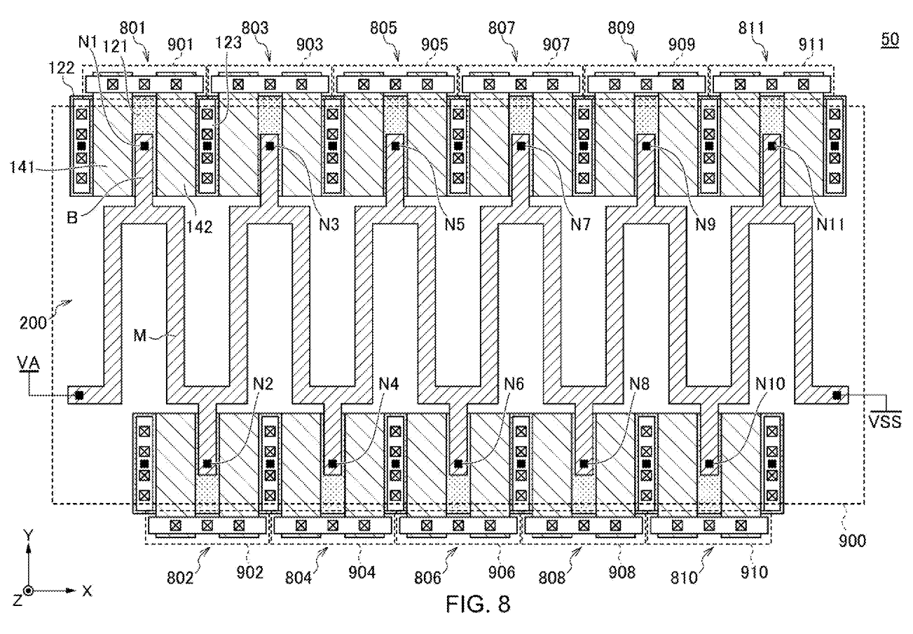

FIG. 8 is a schematic plan view showing a configuration of a resistive voltage divider 50 according to a fifth embodiment of the present disclosure. The resistive voltage divider 50 shown in FIG. 8 includes selection transistors 801 to 811, a resistor pattern 200 connected to the selection transistors 801 to 811, and an output line 900. Each selection signal is supplied to the gate electrode of each of the transistors 801 to 811 via the corresponding one of selection signal lines 901 to 911. The resistor pattern 200 includes a main pattern M connecting the end of the resistor pattern 200 to which the inner potential VA is supplied and the end of the resistor pattern 200 to which the ground potential VSS is supplied in one stroke and a plurality of branch patterns B that are branched from the main pattern M towards respectively corresponding selection transistors 801 to 811. The tip of each of the branch patterns B is located on the diffusion region 121 of the corresponding one of the selection transistors 801 to 811 and the tips constitute the nodes N1 to N11 connected to the diffusion region 121. In this manner, the nodes N1 to N11 of the resistor pattern 200 may be located on the branch patterns B. In this case, it is permissible that the main pattern M does not overlap with the selection transistors 801 to 811.

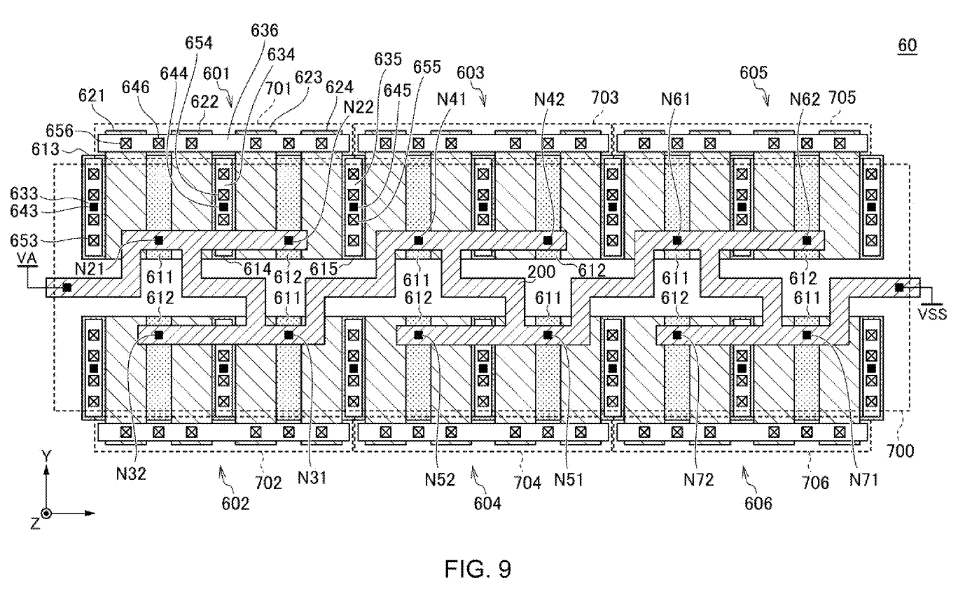

FIG. 9 is a schematic plan view showing a configuration of a resistive voltage divider 60 according to a sixth embodiment of the present disclosure. The resistive voltage divider 60 shown in FIG. 9 includes selection transistors 601 to 606, a resistor pattern 200 that meanders to overlap with the selection transistors 601 to 606, and an output line 700. Each of the selection transistors 601 to 606 includes five diffusion regions 611 to 615 and four gate electrodes 621 to 624. The gate electrode 621 is located between the diffusion regions 611 and 613, the gate electrode 622 is located between the diffusion regions 611 and 614, the gate electrode 623 is located between the diffusion regions 612 and 614, and the gate electrode 624 is located between the diffusion regions 612 and 615. With this configuration, the gate width of each transistor is effectively increased by four times.

The diffusion regions 611 and 612 of the selection transistor 601 are respectively connected to nodes N21 and N22 of the resistor pattern 200. The diffusion regions 611 and 612 of the selection transistor 602 are respectively connected to nodes N31 and N32 of the resistor pattern 200. The diffusion regions 611 and 612 of the selection transistor 603 are respectively connected to nodes N41 and N42 of the resistor pattern 200. The diffusion regions 611 and 612 of the selection transistor 604 are respectively connected to nodes N51 and N52 of the resistor pattern 200. The diffusion regions 611 and 612 of the selection transistor 605 are respectively connected to nodes N61 and N62 of the resistor pattern 200. The diffusion regions 611 and 612 of the selection transistor 606 are respectively connected to nodes N71 and N72 of the resistor pattern 200.

All the nodes N21, N31, N41, N51, N61, and N71 are located on the main pattern M of the resistor pattern 200. On the other hand, all the nodes N22, N32, N42, N52, N62, and N72 are located at the tips of respective branch patterns B. In the present embodiment, a portion of the main pattern M overlaps with the selection transistors 601 to 606 and each of the branch patterns B is branched from the main pattern M at the portion where the main pattern M overlaps with the selection transistors 601 to 606.

The gate electrodes 621 to 624 of the selection transistor 601 are connected to a selection signal line 701 via a via conductor 646, a conductor pattern 636, and a via conductor 656. This configuration also applies to the gate electrodes of other selection transistors 602 to 606 and each selection signal is supplied thereto via the corresponding one of selection signal lines 702 to 706. The diffusion region 613 of the selection transistor 601 is connected to the output line 700 via a via conductor 643, a conductor pattern 633, and a via conductor 653. The diffusion region 614 of the selection transistor 601 is connected to the output line 700 via a via conductor 644, a conductor pattern 634, and a via conductor 654. The diffusion region 615 of the selection transistor 601 is connected to the output line 700 via a via conductor 645, a conductor pattern 635, and a via conductor 655. This configuration also applies to other selection transistors 602 to 606 and diffusion regions that function as sources are connected in common to the output line 700.

In this manner, the configuration of the selection transistors is not limited to any specific one and it is permissible that one selection transistor is formed of five diffusion regions and four gate electrodes.

While the resistor pattern 200 has a meander shape in the embodiments described above, this feature is not essential in the present invention. For example, it is permissible to configure that a plurality of selection transistors are arranged in a line in the X direction, a resistor pattern is arranged to have a linear shape to overlap with the plurality of selection transistors, and the resistor pattern is connected to diffusion regions each of which functions as the drain of each selection transistor.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a resistor pattern having a plurality of nodes; and
a plurality of transistors each having a first diffusion region coupled to an associated one of the plurality of nodes of the resistor pattern and a second diffusion region coupled in common to an output terminal,
wherein each of the plurality of nodes of the resistor pattern is physically located over the first diffusion region of an associated one of the plurality of transistors.

2. The apparatus of claim 1,
wherein the plurality of transistors include first and second transistors, and
wherein the resistor pattern includes a first section coupled between the first diffusion region of the first transistor and the first diffusion region of the second transistor.

3. The apparatus of claim 2,
wherein the first section of the resistor pattern is on a first wiring layer, and
wherein the first diffusion region of the first transistor and the first diffusion region of the second transistor are coupled via the first section of the resistor pattern without routing through an upper wiring on any one of a plurality of upper wiring layers physically located above the first wiring layer.

4. The apparatus of claim 2, further comprising a capacitor element arranged between the first transistor and the second transistor so as to overlap with the first section of the resistor pattern.

5. The apparatus of claim 2,
wherein the plurality of transistors further include a third transistor,
wherein the resistor pattern further includes a second section coupled between the first diffusion region of the second transistor and the first diffusion region of the third transistor, and
wherein the first transistor and the third transistor are arranged in a first direction.

6. The apparatus of claim 5, wherein the second transistor and the first and third transistors are arranged in a second direction different from the first direction.

7. The apparatus of claim 5, wherein the second diffusion region of the first transistor and the second diffusion region of the third transistor are at least partially shared.

8. The apparatus of claim 6,
wherein the plurality of transistors further include a fourth transistor,
wherein the resistor pattern further includes a third section coupled between the first diffusion region of the third transistor and the first diffusion region of the fourth transistor, and
wherein the second transistor and the fourth transistor are arranged in the first direction.

9. The apparatus of claim 8,
wherein the second diffusion region of the first transistor and the second diffusion region of the third transistor are at least partially shared, and
wherein the second diffusion region of the second transistor and the second diffusion region of the fourth transistor are at least partially shared.

10. The apparatus of claim 2,
wherein the resistor pattern having a first end supplied with a first power potential and a second end supplied with a second power potential different from the first power potential,
wherein the plurality of nodes include a first node physically located over the first diffusion region of the first transistor,
wherein the first node of the resistor pattern is closest to the first end of the resistor pattern among the plurality of nodes,
wherein the resistor pattern further includes a second section coupled between the first end and the first node, and
wherein the second section of the resistor pattern is larger in length than the first section of the resistor pattern.

11. The apparatus of claim 10,
wherein the plurality of transistors further include third and fourth transistors,
wherein the resistor pattern further includes a third section coupled between the first diffusion region of the third transistor and the first diffusion region of the fourth transistor,
wherein the plurality of nodes further includes a second node physically located over the first diffusion region of the fourth transistor,
wherein the second node of the resistor pattern is closest to the second end of the resistor pattern among the plurality of nodes,
wherein the resistor pattern further includes a fourth section coupled between the second end and the second node, and
wherein the fourth section of the resistor pattern is larger in length than each of the first and third sections of the resistor pattern.

12. The apparatus of claim 11, wherein the fourth section of the resistor pattern is larger in length than the second section of the resistor pattern.

13. An apparatus comprising:
a resistor pattern having a first end supplied with a first power potential, a second end supplied with a second power potential different from the first power potential, and first and second nodes positioned between the first end and the second end;
a plurality of transistors each having a first diffusion region and a second diffusion region; and
an output power line coupled in common to the second diffusion regions of the plurality of transistors,
wherein the resistor pattern is on a first wiring layer,
wherein the plurality of transistor include a first transistor and a second transistor,
wherein the first diffusion region of the first transistor is coupled to the first node of the resistor pattern,
wherein the first diffusion region of the second transistor is coupled to the second node of the resistor pattern, and
wherein the first node and the second node are coupled via a first section of the resistor pattern without routing through an upper wiring on any one of a plurality of upper wiring layers physically located above the first wiring layer.

14. The apparatus of claim 13, wherein the output power line is on a second wiring layer included in the plurality of upper wiring layers.

15. The apparatus of claim 14,
wherein the resistor pattern includes a main pattern connecting the first end and the second end in one stroke, and
wherein each of the first and second node is on the main pattern of the resistor pattern.

16. The apparatus of claim 14,
wherein the resistor pattern includes a main pattern connecting the first end and the second end in one stroke and a branch pattern branching from the main pattern on the first wiring layer, and
wherein the first node is on the branch pattern of the resistor pattern.

17. The apparatus of claim 14,
wherein the resistor pattern further includes a third node positioned between the second node and the second end,
wherein the plurality of transistor further include a third transistor,
wherein the first diffusion region of the third transistor is coupled to the third node of the resistor pattern, and
wherein the second node and the third node are coupled via a second section of the resistor pattern without routing through an upper wiring on any one of the plurality of upper wiring layers.

18. The apparatus of claim 17, wherein the second diffusion region of the first transistor and the second diffusion region of the third transistor are at least partially shared.

19. An apparatus comprising:
a plurality of first transistors arranged in a first direction;
a plurality of second transistors arranged in the first direction;
a meander-shaped resistor pattern; and
an output power line,
wherein the plurality of first transistors and the plurality of second transistors are arranged in a second direction perpendicular to the first direction,
wherein each of the plurality of first and second transistors includes a first diffusion region and a second diffusion region,
wherein the resistor pattern includes a plurality of first sections extending in the first direction, a plurality of second sections extending in the first direction, and a plurality of third sections extending in the second direction,
wherein each of the plurality of first sections of the resistor pattern overlaps with and coupled to the first diffusion region of an associated one of the plurality of first transistors,
wherein each of the plurality of second sections of the resistor pattern overlaps with and coupled to the first diffusion region of an associated one of the plurality of second transistors,
wherein each of the plurality of third sections of the resistor pattern is coupled between one end of an associated one of the plurality of first sections and one end of an associated one of the plurality of second sections, and
wherein the second diffusion region of the plurality of first and second transistors are coupled in common to the output power line.

20. The apparatus of claim 19,
wherein each of the plurality of first, second, and third sections of the resistor pattern is on a first wiring layer without routing through an upper wiring on any one of a plurality of upper wiring layers physically located above the first wiring layer, and
wherein the output power line is on a second wiring layer included in the plurality of upper wiring layers.
